(19) United States
(12) Patent Application Publication
(10) Pub. No.: US 2016/0123565 A1
(43) Pub. Date: May 5, 2016

(54) CIRCUIT BOARD FOR DRIVING FLIP-CHIP LIGHT EMITTING CHIP AND LIGHT EMITTING MODULE COMPRISING THE SAME

(71) Applicant: Genesis Photonics Inc., Tainan City (TW)

(72) Inventors: Cheng-Wei Hung, Tainan City (TW); Meng-Ting Tsai, Tainan City (TW); Yu-Feng Lin, Tainan City (TW)

(21) Appl. No.: 14/927,456

(22) Filed: Oct. 29, 2015

(30) Foreign Application Priority Data
Oct. 30, 2014 (TW) 103137687

(51) Int. Cl. F21V 23/00; H05K 3/00; H05K 1/05

(52) U.S. Cl. CPC F21V 23/006; H05K 1/05; H05K 3/0011; H05K 2201/09227; H05K 2201/09036; H05K 2201/10106; H05K 2201/10674; H05K 2201/2054

(57) ABSTRACT

A circuit board for driving a flip-chip light emitting chip is disclosed. The circuit board includes a metal substrate having a first surface and a second surface, the first surface including a first electrode area, a second electrode area and a heat conduction area; a first metal electrode formed on the first electrode area for providing a first voltage; a first insulation layer formed between the first metal electrode and the metal substrate; a second metal electrode formed on the second electrode area for providing a second voltage; a second insulation layer formed between the second metal electrode and the metal substrate; and a solder resist layer covering the first surface; wherein the heat conduction area is exposed from the solder resist layer.

### BACKGROUND OF THE INVENTION

1. Field of the Invention

The present invention relates to a circuit board for driving a flip-chip light emitting chip and a light emitting module, and more particularly, to a circuit board for driving a flip-chip light emitting chip and a light emitting module capable of improving heat dissipation efficiency.

2. Description of the Prior Art

Since light emitting diodes (LEDs) have advantages of long service life, small size and low power consumption, the light emitting diodes are widely used in various kinds of illumination devices. Generally, when temperature of the light emitting diodes rises, light emitting efficiency of the light emitting diodes is significantly decreased and service life of the light emitting diodes is reduced as well. As the light emitting diodes are gradually used for various kinds of illumination devices, the heat dissipation problem of the light emitting diodes becomes more important.

In the prior art, a substrate for carrying light emitting diodes is made of aluminum oxide (Al₂O₃) or other materials with insulation and high heat-conductive characteristics, so as to dissipate heat of the light emitting diodes. However, thermal conductivity of the aluminum oxide is still lower than thermal conductivity of a metal material. Therefore, the prior art cannot further improve heat dissipation efficiency of a light emitting diode illumination device.

### SUMMARY OF THE INVENTION

The present invention provides a circuit board for driving a flip-chip light emitting chip and a light emitting module, in order to solve the problems of the prior art.

The circuit board for driving the flip-chip light emitting chip of the present invention comprises a metal substrate having a first surface and a second surface opposite to the first surface, the first surface comprising a first electrode area, a second electrode area and a heat conduction area; a first metal electrode formed on the first electrode area for providing a first voltage; a first insulation layer formed between the first metal electrode and the metal substrate; a second metal electrode formed on the second electrode area for providing a second voltage; a second insulation layer formed between the second metal electrode and the metal substrate; and a solder resist layer covering the first surface of the metal substrate; wherein the heat conduction area is exposed from the solder resist layer.

The light emitting module of the present invention comprises a flip-chip light emitting chip and a circuit board. The flip-chip light emitting chip comprises a first electrode and a second electrode. The circuit board comprises a metal substrate having a first surface and a second surface opposite to the first surface, the first surface comprising a first electrode area, a second electrode area and a heat conduction area; a first metal electrode formed on the first electrode area for providing a first voltage to the first electrode of the flip-chip light emitting chip; a first insulation layer formed between the first metal electrode and the metal substrate; a second metal electrode formed on the second electrode area for providing a second voltage to the second electrode of the flip-chip light emitting chip; a second insulation layer formed between the second metal electrode and the metal substrate; and a solder resist layer covering the first surface of the metal substrate; wherein the heat conduction area is exposed from the solder resist layer and the heat conduction area is connected to the flip-chip light emitting chip.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram showing a circuit board of a flip-chip light emitting chip of the present invention.

FIG. 2 is a cross-sectional view of the circuit board of the flip-chip light emitting chip in FIG. 1.

FIG. 3 is a diagram showing a light emitting module according to a first embodiment of the present invention.

FIG. 4 is a diagram showing a light emitting module according to a second embodiment of the present invention.

### DETAILED DESCRIPTION

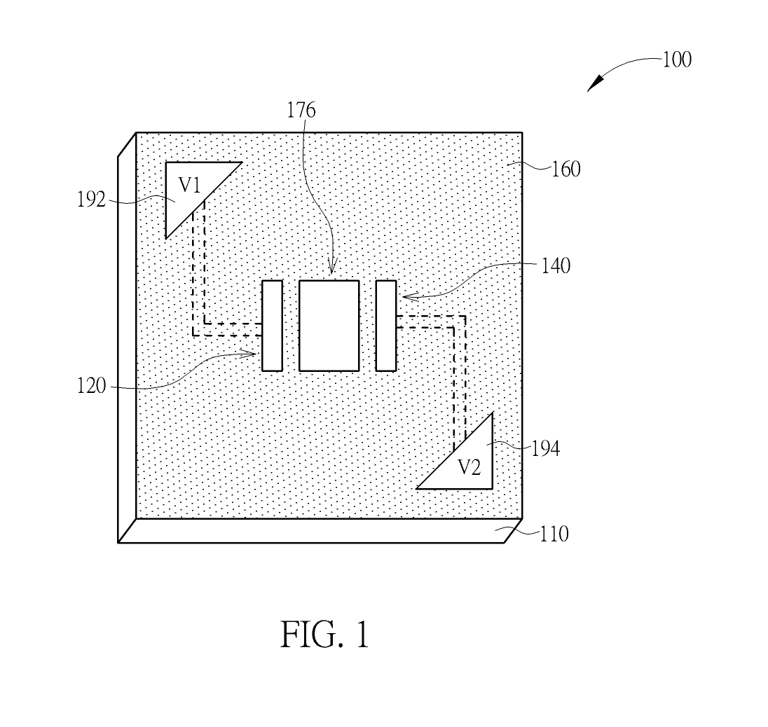

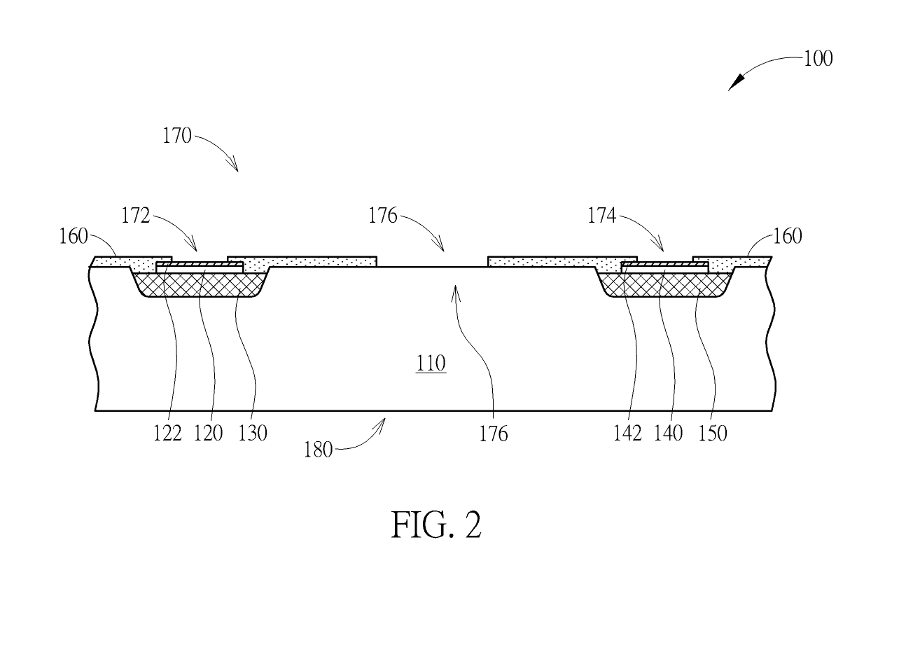

Please refer to FIG. 1 and FIG. 2. FIG. 1 is a diagram showing a circuit board of a flip-chip light emitting chip of the present invention. FIG. 2 is cross-sectional view of the circuit board of the flip-chip light emitting chip in FIG. 1. As shown in figures, the circuit board 100 of the flip-chip light emitting chip comprises a metal substrate 110, a first metal electrode 120, a first insulation layer 130, a second metal electrode 140, a second insulation layer 150 and a solder resist layer 160. The metal substrate 110 has a first surface 170, and a second surface 180 opposite to the first surface 170. The first surface 170 comprises a first electrode area 172, a second electrode area 174 and a heat conduction area 176. The first electrode area 172 and the second electrode area 174 can be recessed areas formed by etching the first surface, but the present invention is not limited thereto. The first metal electrode 120 is formed on the first electrode area 172. The first insulation layer 130 is formed between the first metal electrode 120 and the metal substrate 110, in order to prevent conduction between the first metal electrode 120 and the metal substrate 110. The second metal electrode 140 is formed on the second electrode area 174. The second insulation layer 150 is formed between the second metal electrode 140 and the metal substrate 110, in order to prevent conduction between the second metal electrode 140 and the metal substrate 110. Due to the arrangement of the first insulation layer 130 and the second insulation layer 150, the heat conduction area 176 is not electrically connected to the first metal electrode 120 and the second metal electrode 140. The solder resist layer 160 is formed to cover the first surface 170 of the metal substrate 110. The solder resist layer 160 can prevent solder from flowing around, and has an insulation function. The heat conduction area 176 is exposed from the solder resist layer 160.

In addition, the circuit board 100 of the present invention can further comprise a first power electrode 192 and a second power electrode 194. The first power electrode 192 can be electrically connected to the first metal electrode 120, and is configured to receive a first voltage V1 (such as a positive voltage). The second power electrode 194 can be electrically connected to the second metal electrode 140, and is configured to receive a second voltage V2 (such as a ground voltage) different from the first voltage V1. As such, the first metal electrode 120 and the second metal electrode 140 can respectively provide the first voltage V1 and the second voltage V2 to a flip-chip light emitting chip, for driving the flip-chip light emitting chip to emit light. Moreover, the circuit board 100 of the present invention can further comprise a first anti-oxidative metal layer 122 formed on the first metal electrode 120, and a second anti-oxidative metal layer 142 formed on the second metal electrode 140. The first anti-oxidative metal layer 122 and the second anti-oxidative metal layer 142 can be made of gold or silver, in order to prevent the first metal electrode 120 and the second metal electrode 140 from being oxidized.

On the other hand, the circuit board of the present invention can comprise a plurality of first metal electrodes 120, second metal electrodes 140, and heat conduction areas 176. The plurality of first metal electrodes 120, second metal electrodes 140, and heat conduction areas 176 can be evenly distributed on the circuit board in a circular or array form. As such, when the circuit board of the present invention provides power to a plurality of flip-chip light emitting chips for driving the plurality of flip-chip light emitting chips to emit light, the circuit board of the present invention can rapidly and uniformly dissipate heat of the plurality of flip-chip light emitting chips. Moreover, when the circuit board of the present invention comprises the plurality of first metal electrodes 120, second metal electrodes 140, and heat conduction areas 176, electrical connections (such as serial connection or parallel connection) among the first metal electrodes 120, the second metal electrodes 140, the first power electrode 192, and the second power electrode 194 can vary according to design requirements.

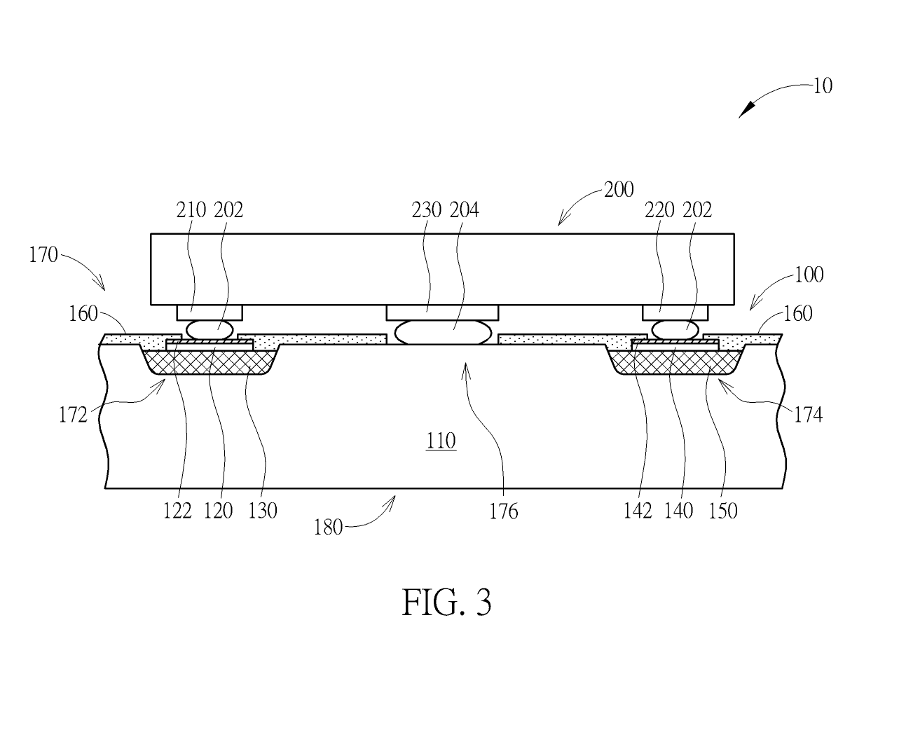

Please refer to FIG. 3. FIG. 3 is a diagram showing a light emitting module according to a first embodiment of the present invention. As shown in FIG. 3, a flip-chip light emitting chip 200 of the present invention can be arranged on the circuit board 100, so as to form a light emitting module 10. The circuit board 100 in FIG. 3 is identical to the circuit board 100 in FIG. 2. Thus no further illustration for the circuit board is provided. The flip-chip light emitting chip 200 comprises a first electrode 210 and a second electrode 220. The first metal electrode 120 of the circuit board 100 can be electrically connected to the first electrode 210 of the flip-chip light emitting chip 200 via solder paste 202, for providing the first voltage V1 to the first electrode 210 of the flip-chip light emitting chip 200. The second metal electrode 140 of the circuit board 100 can be electrically connected to the second electrode 220 of the flip-chip light emitting chip 200 via solder paste 202 as well, for providing the second voltage V2 to the second electrode 220 of the flip-chip light emitting chip 200. In addition, the heat conduction area 176 can be connected to the flip-chip light emitting chip 200 through a heat dissipation material 204 (such as solder paste or heat dissipation paste) . In other embodiments of the present invention, the heat conduction area 176 can be directly connected to the flip-chip light emitting chip 200 as well.

According to the above arrangement, heat generated by the flip-chip light emitting chip 200 when emitting light can be rapidly guided to the metal substrate 110 by the heat conduction area 176, and the heat can be further dissipated by the metal substrate 110. In one embodiment of the present invention, the metal substrate 110 can be a copper substrate. Since thermal conductivity of copper is higher than thermal conductivity of aluminum oxide, the circuit board 100 of the present invention can improve heat dissipation efficiency. Moreover, the flip-chip light emitting chip 200 can further comprise a heat dissipation metal sheet 230 without being electrically connected to the first electrode 210 and the second electrode 220. The heat conduction area 176 can be connected to the heat dissipation metal sheet 230 of the flip-chip light emitting chip 200 via the heat dissipation material 204 (or directly connected to the heat dissipation metal sheet 230), in order to further improve heat dissipation efficiency.

On the other hand, the solder resist layer 160 can be made of a light reflective material for reflecting light emitted by the flip-chip light emitting chip 200, such that light emitting efficiency of the light emitting module 10 can be improved. In one embodiment of the present invention, the flip-chip light emitting chip 200 is a flip-chip light emitting diode chip, but the present invention is not limited thereto.

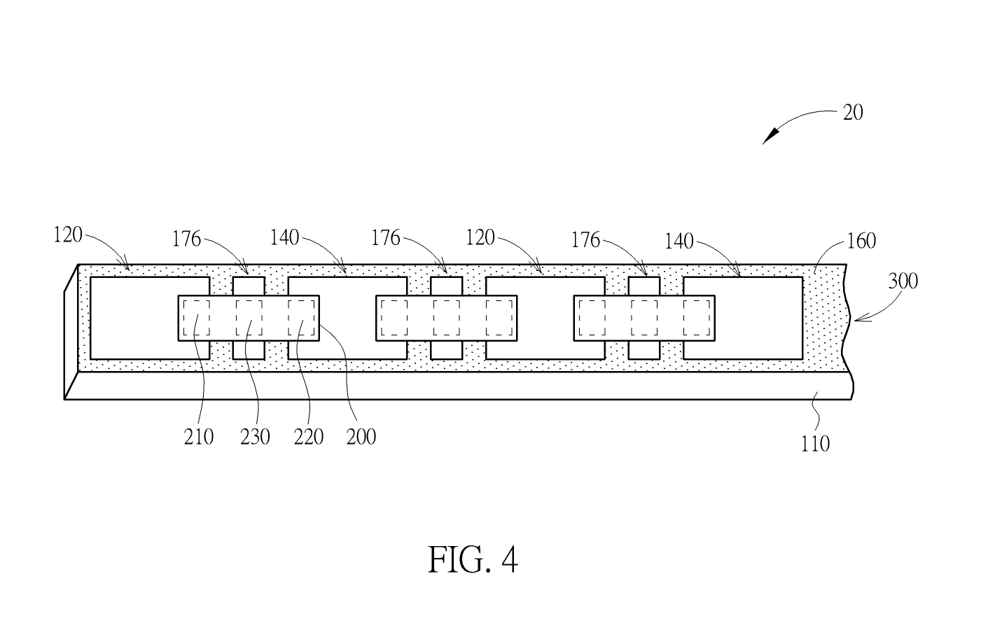

Please refer to FIG. 4. FIG. 4 is a diagram showing a light emitting module according to a second embodiment of the present invention. As shown in FIG. 4, a light emitting module 20 of the present invention comprises a plurality of flip-chip light emitting chips 200 connected in series on a circuit board 300, for further forming alight strip. Arrangement of first metal electrodes 120, second metal electrodes 140, and heat conduction areas 176 in FIG. 4 can refer to FIG. 2. The flip-chip light emitting chip 200 in FIG. 4 can be identical to the flip-chip light emitting chip 200 in FIG. 3, but the present invention is not limited thereto. In the light emitting module 20 in FIG. 4, only two metal electrodes at head and tail ends are respectively coupled to a positive voltage source and a ground voltage source, and middle metal electrodes between the head and tail metal electrodes are shared, in order to drive the flip-chip light emitting chip 200 to emit light. In addition, the heat conduction area 176 can be connected to the flip-chip light emitting chips 200 through the heat dissipation material, or the heat conduction area 176 can be directly connected to the flip-chip light emitting chips 200 as well.

According to the above arrangement, heat generated by each of the flip-chip light emitting s 200 when emitting light can be rapidly guided to the metal substrate 110 by the corresponding heat conduction area 176, and the heat can be further dissipated by the metal substrate 110, so as to improve heat dissipation efficiency.

In contrast to the prior art, the present invention utilizes the metal substrate as a circuit substrate of the flip-chip light emitting chip, and the metal substrate has an exposed heat conduction area for being indirectly or directly connected to the flip-chip light emitting chip, in order to rapidly guide heat generated by the flip-chip light emitting chip when emitting light to the metal substrate via the heat conduction area, and to further dissipate heat by the metal substrate. Therefore, the circuit board of the flip-chip light emitting chip and the light emitting module of the present invention have better heat dissipation efficiency.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A circuit board for driving a flip-chip light emitting chip, the circuit board comprising:
a metal substrate having a first surface and a second surface opposite to the first surface, the first surface comprising a first electrode area, a second electrode area and a heat conduction area;
a first metal electrode formed on the first electrode area for providing a first voltage;
a first insulation layer formed between the first metal electrode and the metal substrate;
a second metal electrode formed on the second electrode area for providing a second voltage;
a second insulation layer formed between the second metal electrode and the metal substrate; and
a solder resist layer covering the first surface of the metal substrate;
wherein the heat conduction area is exposed from the solder resist layer.

2. The circuit board of claim 1, wherein the solder resist layer is made of a light reflective material.

3. The circuit board of claim 1, wherein the solder resist layer is formed on the first metal electrode, and the solder resist layer directly contacts a side wall of the first metal electrode.

4. The circuit board of claim 1, wherein the solder resist layer is formed on the first insulation layer.

5. The circuit board of claim 1, wherein the solder resist layer directly covers a side wall of the first electrode area.

6. The circuit board of claim 1, wherein the solder resist layer and the first metal electrode completely cover the first insulation layer.

7. The circuit board of claim 1, wherein a width of the first metal electrode is smaller than a width of the first insulation layer.

8. The circuit board of claim 1 further comprising:
a first anti-oxidative metal layer formed on the first metal electrode; and
a second anti-oxidative metal layer formed on the second metal electrode.

9. The circuit board of claim 1, wherein the first electrode area and the second electrode area are formed by etching the first surface.

10. A light emitting module, comprising:
a flip-chip light emitting chip comprising a first electrode and a second electrode; and
a circuit board, comprising:
a metal substrate having a first surface and a second surface opposite to the first surface, the first surface comprising a first electrode area, a second electrode area and a heat conduction area;
a first metal electrode formed on the first electrode area for providing a first voltage to the first electrode of the flip-chip light emitting chip;
a first insulation layer formed between the first metal electrode and the metal substrate;
a second metal electrode formed on the second electrode area for providing a second voltage to the second electrode of the flip-chip light emitting chip;
a second insulation layer formed between the second metal electrode and the metal substrate; and
a solder resist layer covering the first surface of the metal substrate;
wherein the heat conduction area is exposed from the solder resist layer and the heat conduction area is connected to the flip-chip light emitting chip.

11. The light emitting module of claim 10, wherein the solder resist layer is made of a light reflective material.

12. The light emitting module of claim 10, wherein the solder resist layer is formed on the first metal electrode, and the solder resist layer directly contacts a side wall of the first metal electrode.

13. The light emitting module of claim 10, wherein the solder resist layer is formed on the first insulation layer.

14. The light emitting module of claim 10, wherein the solder resist layer directly covers a side wall of the first electrode area.

15. The light emitting module of claim 10, wherein the solder resist layer and the first metal electrode completely cover the first insulation layer.

16. The light emitting module of claim 10, wherein a width of the first metal electrode is smaller than a width of the first insulation layer.

17. The light emitting module of claim 10 further comprising:
a first anti-oxidative metal layer formed on the first metal electrode; and
a second anti-oxidative metal layer formed on the second metal electrode.

18. The light emitting module of claim 10, wherein the first electrode area and the second electrode area are formed by etching the first surface.

19. The light emitting module of claim 10, wherein the flip-chip light emitting chip further comprises a heat dissipation metal sheet not electrically connected to the first electrode and the second electrode, and the heat conduction area is connected to the heat dissipation metal sheet of the flip-chip light emitting chip.
